(19) United States
(12) Patent Application Publication
(10) Pub. No.: US 2005/0195640 A1
(43) Pub. Date: Sep. 8, 2005

(54) Two-component, rectifying-junction memory element

(76) Inventors: Shawn Smith, Poughkeepsie, NY (US); Stephen R. Forrest, Princeton, NJ (US)

Correspondence Address: OLYMPIC PATENT WORKS PLLC, P.O. BOX 4277, SEATTLE, WA, 98104, US

(21) Appl. No.: 10/998,187

(22) Filed: Nov. 26, 2004

Related U.S. Application Data
(60) Provisional application No. 60/525,056, filed on Nov. 25, 2003.

(51) Int. Cl. G11C 13/00

(52) U.S. Cl. 365/151

(57) ABSTRACT

Embodiments of the present invention are directed to low complexity, efficient, two-component memory elements for use in low-cost, robust, and reliable WORM memories. The memory element of one embodiment is an organic-on-inorganic heterojunction diode comprising an organic-polymer layer joined to a doped, inorganic semiconductor layer. The organic polymer layer serves both as one later of a two-later, semiconductor-based diode, as well as a fuse. Application of a voltage greater than a threshold WRITE voltage for a period of time greater than a threshold time interval for a WRITE-voltage pulse irreversibly and dramatically increases the resistivity of the organic polymer layer. The memory element that represents one embodiment of the present invention is more easily manufactured than previously described, separate-fuse-and-diode memory elements, and has the desirable characteristics of being switchable at lower voltages and with significantly shorter-duration WRITE-voltage pulses than the previously described memory elements.

### CROSS-REFERENCE TO RELATED APPLICATION

This application claims the benefit of Provisional Application No. 60/525,056, filed Nov. 25, 2003.

### TECHNICAL FIELD

The present invention relates to electronic switches and switch-based memory elements and, in particular, to a robust, efficient, easy-to-manufacture two-component memory element with a low WRITE-voltage threshold and a short WRITE-voltage-pulse-length threshold.

### BACKGROUND OF THE INVENTION

Digital information storage has become, over the course of the past decade, a foundation technology for an ever-increasing panoply of consumer products, from personal computers to personal digital assistants, digital cameras, recorded music and entertainment, and many additional products. Many different types of digital-information-storage media are currently available, including magnetic disks, compact discs, and solid-state electronic memories and flash memories. Different types of digital-information-storage media, and electronic devices for storing information to, and retrieving information from, digital-information-storage media have different characteristics and costs. Due to the increasing popularity of digital cameras and other widely used, relatively low-cost consumer electronic devices that store and retrieve digital information, a need has developed for highly robust and reliable digital-information-storage media that are stable for long periods of time, and relatively insensitive to mechanical shock, temperature changes, and exposure to various different chemical environments. For digital photography applications, useful digital-information-storage media include low cost, write-once, read-many-times (“WORM”) storage media, known as “WORM” memories.

An electronic memory essentially comprises a large number of binary switches, the states of which can be accessed for writing and reading by an electronic-information-storage-and-retrieval device. Each memory element, or switch, can store, one of the two Boolean values “0” or “1” at a given time. A robust and reliable WORM memory accurately receives and stores the binary data written to it, and accurately returns stored data requested during READ operations. In other words, when an electronic-information-storage-and-retrieval device directs that the Boolean value “1” be written to a particular memory element, a reliable WORM needs to store the Boolean value “1,” as a switch state, with very high probability. A reliable WORM memory also needs to, with very high probability, correctly identify and return the state of a switch, or memory element, during READ operations. Finally, the WORM memory must be chemically and electronically stable, so that switch states remain constant over long periods of time, despite various types of environmental insults and internal deteriorative processes. In addition to being reliable and robust, a WORM memory suitable for many consumer-product applications needs to be easily and cheaply manufactured. For example, large amounts of WORM memory are needed for storing digital images, in much the same way that expose-once, silver-impregnated polymer films are used to store photographic images in conventional, film-based photography.

Recently, progress has been made in developing low-cost, reliable WORM memories based on semiconductor diodes and organic-polymer fuses. These WORM memories can be produced using well-known semiconductor manufacturing techniques used for manufacturing traditional semiconductor-based memories and integrated circuits (“ICs”). However, manufacturers and users of digital-information-storage media continue to seek lower cost, more easily manufactured, and more efficiently employable digital-information-storage media.

### SUMMARY OF THE INVENTION

Certain embodiments of the present invention are directed to low complexity, efficient, two-component memory elements for use in low-cost, robust, and reliable WORM memories. The memory element of one embodiment is an organic-on-inorganic heterojunction diode comprising an organic-polymer layer joined to a doped, inorganic semiconductor layer. The organic polymer layer serves both as one layer of a two-layer, semiconductor-based diode and as a fuse. Application of a voltage greater than a threshold WRITE voltage for a period of time greater than a threshold time interval for a WRITE-voltage pulse irreversibly and dramatically increases the resistivity of the organic polymer layer. The memory element that represents one embodiment of the present invention is more easily manufactured than previously described, separate-fuse-and-diode memory elements, and has the desirable characteristics of being switchable at lower voltages and with significantly shorter-duration WRITE-voltage pulses than the previously described memory elements.

### BRIEF DESCRIPTION OF THE DRAWINGS

FIG. 1 shows one type of WORM memory.

FIG. 2 shows a read operation directed to memory element 120 of the passive matrix memory shown in FIG. 1.

FIGS. 3-5, along with FIG. 2, illustrate a method by which the passive matrix WORM memory, shown in FIG. 1, is accessed during READ and WRITE operations.

FIG. 6 illustrates current-flow problems that result from bidirectional passage of current by memory elements in a passive matrix WORM memory.

FIGS. 7-10 illustrate memory-element properties important for creation of efficient, robust, and reliable WORM memories.

FIG. 11 shows a representation of valence and conduction bands of a semiconductor.

FIGS. 12-16 illustrate a diode component within a memory element.

FIGS. 17A-B shows a complete, previously described memory element including both a fuse component and a diode and a schematic representation of the memory-element.

FIG. 18 shows the chemical structure of the PEDT/PSS polymer mixture, known by the trade name “Baytron® P.”

FIG. 19 shows a first memory-element embodiment of the present invention.

FIG. 20 shows a second memory-element embodiment of the present invention.

FIG. 21 illustrates a general manufacturing method for one type of CME that represents one embodiment of the present invention.

FIGS. 22A-B show the quasi-static conductivity switching characteristics of prototype memory elements that represent embodiments of the present invention.

FIG. 23 shows the relationships between current densities and applied voltage for a prototype memory element that represents one embodiment of the present invention before and after application of a WRITE voltage pulse.

FIG. 24 shows the relationship between current density and time during application of a voltage pulse to a prototype memory element that represents one embodiment of the present invention.

### DETAILED DESCRIPTION OF THE INVENTION

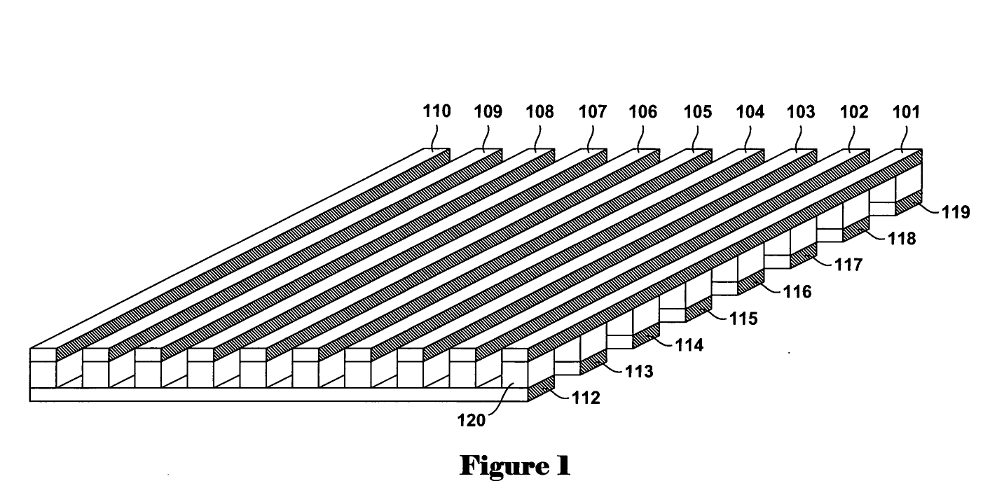

One embodiment of the present invention is directed to an efficient, easily manufactured organic-on-inorganic heterojunction memory element for WORM memories. There are many different types of WORM memories currently produced and used for various different applications. FIG. 1 shows one type of WORM memory. The WORM memory comprises a first set of parallel signal lines 101-110 separated from a second set of parallel signal lines, roughly perpendicular to the first set of parallel signal lines, by memory elements. Individual memory elements, such as memory element 120, are located in the regions of overlap between signal lines of the first set of signal lines and signal lines of the second set of signal lines. Each memory element can be indexed with respect to a particular signal line in the first set of signal lines, referred to as “columns,” and a particular signal line in the second set of signal lines, referred to as “rows.” In other words, the passive matrix WORM memory is organized as a two-dimensional array of memory elements, each memory element addressable by a row number and a column number, just as elements of a mathematical array are addressed by row and column indices.

A memory element, such as memory element 120 in FIG. 1, stores one of the Boolean values “0” and “1.” The memory element must therefore have at least two different, stable, physical states that can be detected by a digital-information-storage-and-retrieval device. In the WORM memory shown in FIG. 1, each memory element can be in either a low resistance state, and can therefore conduct appreciable currents at applied READ voltages of reasonable, low magnitudes, or can be in a high resistance state, in which the memory element passes only a small current, or no current, when READ voltages are applied.

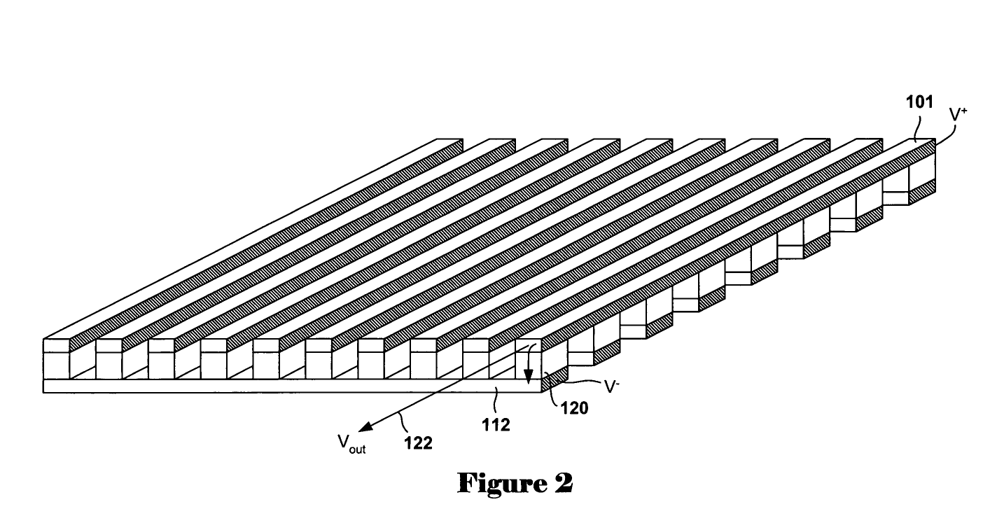

FIG. 2 shows a read operation directed to memory element 120 of the passive matrix memory shown in FIG. 1. A voltage V⁺ is applied to column 101, and a voltage V⁻ is applied to row 112, therefore resulting in a total applied voltage of 2V. When memory element 120 is in a high-resistance state, the voltage read from column 101, Vₒᵤₜ 122, is nearly equal to the applied positive voltage V⁺. However, when memory element 120 is in a low-resistance state, then the voltage read from column 101, Vₒᵤₜ 122, is significantly lower than the applied positive voltage V⁺, approaching voltage V⁻, depending on various resistances and other characteristics of the detection circuit of the digital-information-storage-and-retrieval device that applies the voltages in order to read the state of the memory element. Alternatively, a difference between a current applied to column 101 and a current output from column 1 may be used to determine the resistance state of memory element 120. Note that the applied V⁺ and V⁻ voltages indicate relative voltages, rather than absolute potentials. Note also that two different conventions for voltage polarity may be used. In the current discussion, electrons flow from relatively positive voltage to relatively negative voltage. Memory elements can be designed to switch in response to different applied WRITE voltage polarities of a first magnitude range, with READ operations employing corresponding voltage polarities of a second magnitude range.

READ operations, such as the READ operation shown in FIG. 2, are normally carried out by applying relatively low magnitude READ voltages, at which the resistance state of memory elements remains stable and constant. By contrast, WRITE operations employ a larger WRITE voltage, resulting in relatively high, transient current densities within the memory element. At these elevated current densities, the memory element undergoes a generally irreversible electrochemical change, and transitions from an initially low-resistance state to a high-resistance state. In the WORM memory discussed with reference to FIG. 1, the memory elements are all in low-resistance states following manufacture, and each memory element can be written, one time, by changing the resistance state of the memory element to a high-resistance state. Either of two possible assignments of resistance states to Boolean values may be used. In the current discussion, the low-resistance state of a memory element following manufacture is considered to represent the Boolean value “1,” and the high-resistance state following a WRITE voltage pulse of relatively large magnitude is considered to represent the Boolean value “0.”

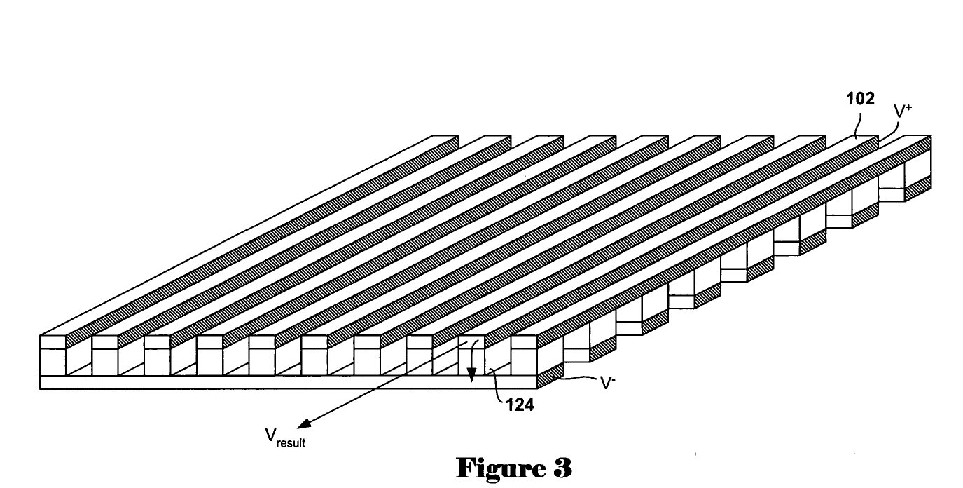

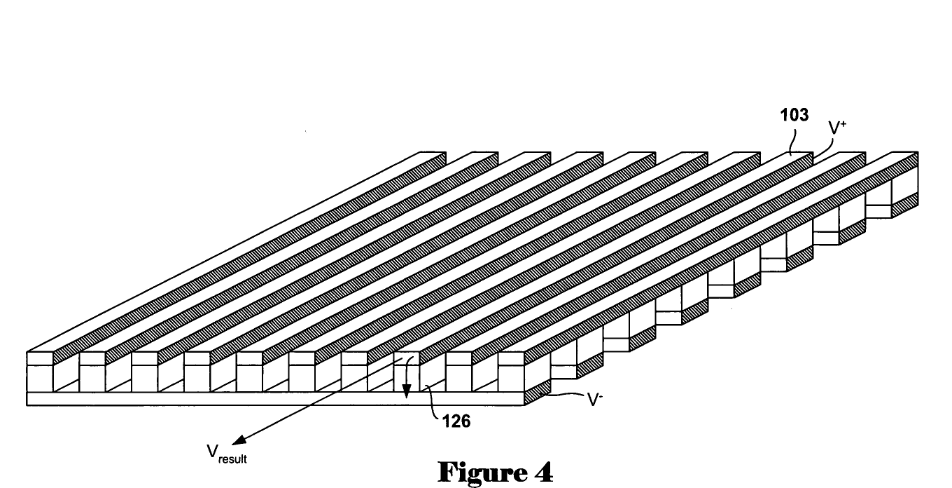

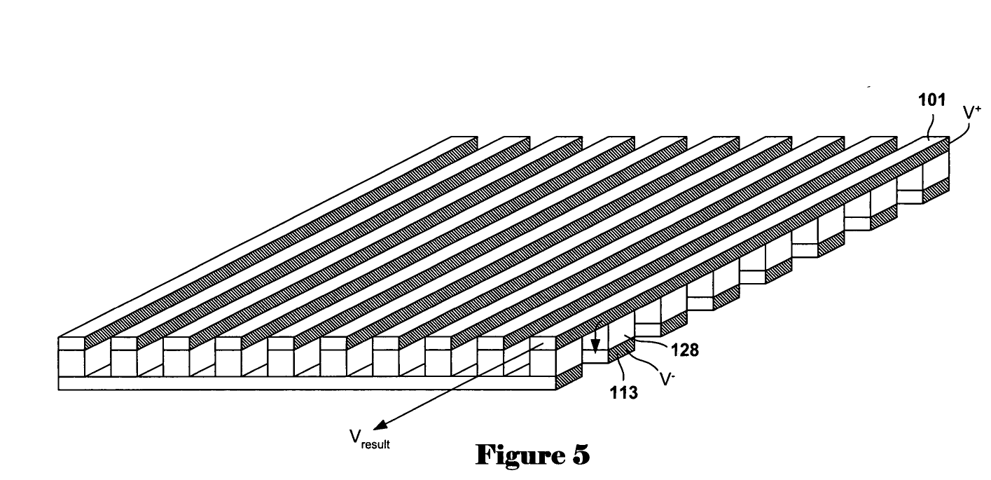

FIGS. 3-5, along with FIG. 2, illustrate a method by which the passive matrix WORM memory, shown in FIG. 1, is accessed during READ and WRITE operations. A voltage V⁻ is applied to a first row, row 112 in FIGS. 2-4, and a voltage V⁺ is successively applied to successive columns, beginning with column 101 in FIG. 2. Application of the voltage V⁺ to column 101, as shown in FIG. 2, results in either reading or writing memory element 120, depending on the magnitude of the total voltage 2 V applied to the memory element via column 101 and row 112. Next, the voltage V⁺ is applied to the second column 102 in order to read or write memory element 124. The process continues, in FIG. 4, with application of Voltage V⁺ to column 103 in order to read the state of memory element 126. This process continues by applying voltage V⁺ to each successive column in the passive matrix WORM memory, while the voltage V⁻ is continuously applied to row 112. Then, as shown in FIG. 5, voltage V⁻ is applied to row 113, and the voltage V⁺ is applied to column 101 to read the state of memory element 128. Voltage V⁺ is successively applied to each successive column, in turn, to read the memory elements overlying row 113.

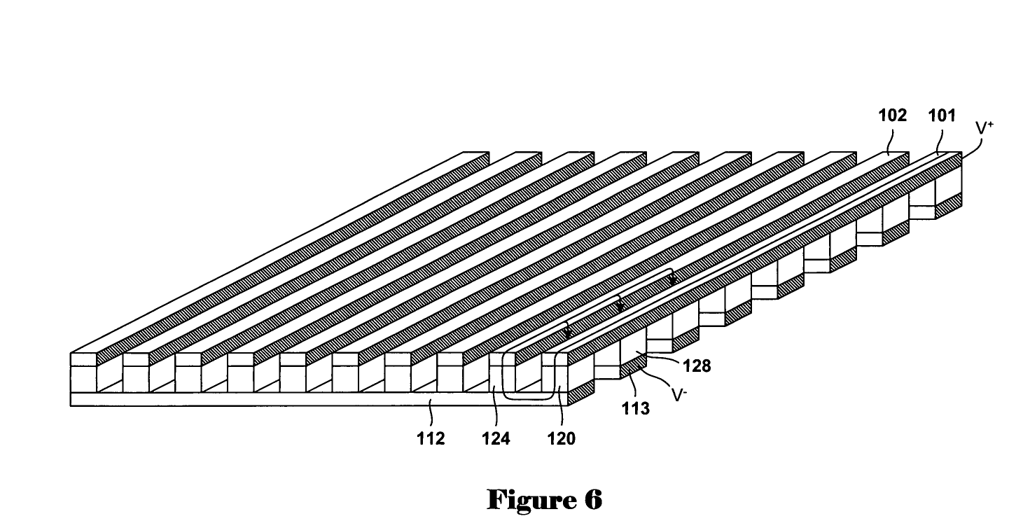

Each memory element needs to pass current in only a single direction. FIG. 6 illustrates current-flow problems that result from bidirectional passage of current by memory elements in a passive matrix WORM memory. In FIG. 6, voltage V⁺ is applied to column 101, and voltage V⁻ is applied to row 113 in order to read the state of memory element 128. In the case shown in FIG. 6, memory element 128 is in a high-resistance state, and therefore passes relatively little current. However, if current flow through memory elements is bidirectional, then the current may instead flow through memory element 120 to row 112, up through memory element 124 in the reverse direction to column 102, and then down through a memory element not shown in FIG. 6 to row 113. Thus, the voltage or current signal read from column 101 will appear to indicate passage of current through memory element 128, even though memory element 128 is in a high-resistance state.

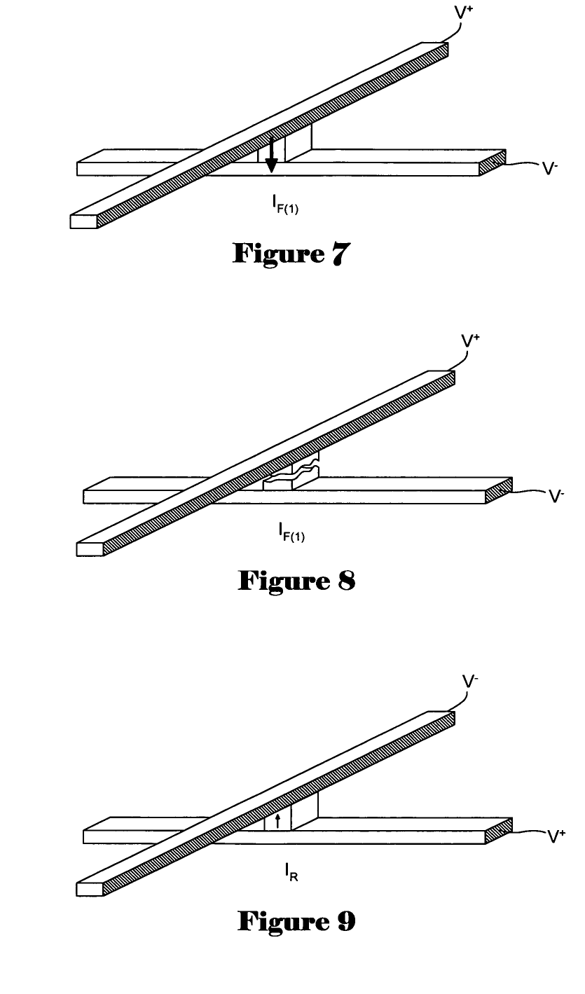

FIGS. 7-10 illustrate memory-element properties important for creation of efficient, robust, and reliable WORM memories. First, as shown in FIG. 7, the memory element needs to support reasonably large current densities when in the low-resistance state corresponding to Boolean value “1.” In other words, the state that represents the Boolean value “1” should have sufficiently low resistance to pass sufficient current to produce a detectable voltage or current difference between applied and output voltages at reasonably low magnitude READ voltages. As the resistance of the memory-element components increases, the applied voltages needed to read the states of the memory elements increases, increasing the power consumed by a digital-information-storage-and-retrieval device accessing the WORM memory in order to read the contents of the WORM memory.

Second, as shown in FIG. 8, the resistivity of the memory-component materials of the memory element in the high-resistance state associated with Boolean value “0” needs to be relatively high. The number of memory elements that can be reliably accessed from a particular row or column of a passive matrix WORM memory is related to the ratio of the currents passed by the memory element in the low-resistance and high-resistance states,

$$\frac{{I}_{{F}_{1}}}{{I}_{{F}_{0}}} .$$

As the ratio

$$\frac{{I}_{{F}_{1}}}{{I}_{{F}_{0}}}$$

decreases, fewer memory elements can be accessed along a given row or column at or above a needed signal-to-noise ratio.

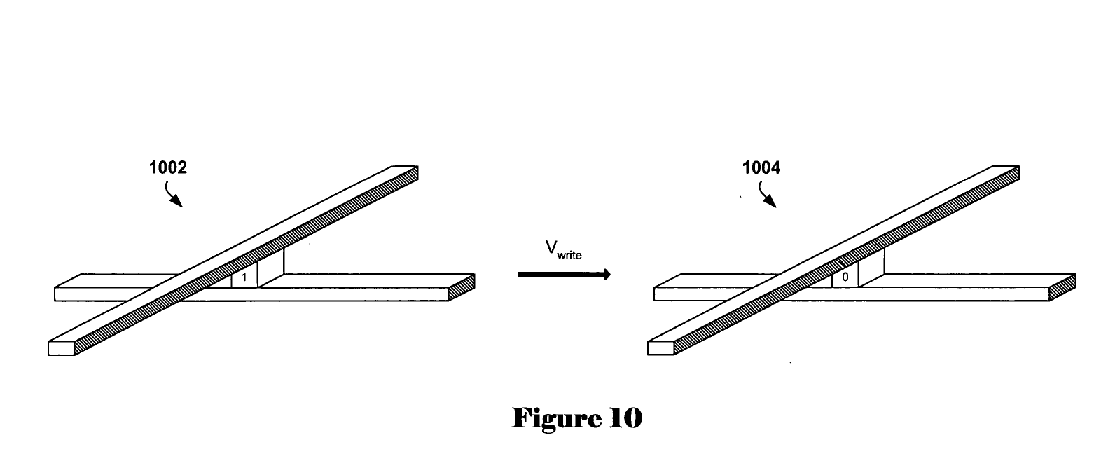

Third, as shown in FIG. 9, the reverse current flow I_{R} of the memory element, regardless of which resistance state the memory element is in, needs to be relatively low, to prevent undesirable current flow within the passive matrix WORM memory, as discussed above, with respect to FIG. 6. Finally, as shown in FIG. 10, the time required to switch the memory element from the low-resistance state associated with Boolean value “0” 1002 to the high-resistance state associated with Boolean value “1” 1004 by applying a WRITE voltage, V_{write}, of relatively large magnitude needs to be as short as possible. As discussed above, with reference to FIGS. 2-5, a passive matrix WORM memory is written sequentially. Therefore, the total time required to write the memory is directly proportional to the time required to write each memory element. Useful WORM memories may have at least tens of millions to hundreds of millions, or more, of memory elements, and memory storage requirements continue to increase with increasing resolution of digital cameras and digital display devices. Therefore, even relatively modest decreases in individual memory-element WRITE operation times can represent significant real-time savings in WORM memory WRITE operations.

In order to address the need for a low reverse current I_{R}, as discussed above with respect to FIG. 9, memory elements commonly incorporate a diode component. Diodes are commonly and routinely fabricated at microscale and submicroscale dimensions on semiconductor substrates. FIG. 11 shows a representation of valence and conduction bands of a semiconductor. The electrons in materials occupy molecular orbitals. Molecular orbitals include valence-band orbitals 1102 and conduction-band orbitals 1104. Energy bands, such as the valence and conduction bands 1102 and 1104 represent many molecular orbital closely spaced in energy. There is, in semiconductor materials, a relatively narrow energy gap, or band gap 1106, between the highest-energy valence-band orbital 1108 and the lowest energy conduction-band orbital 1110. In semiconductor materials at room temperature, most electrons occupy valence-band orbitals. The conduction-band orbitals are mostly unoccupied. Valence-band orbitals tend to be localized with respect to particular atoms of a material, while conduction band orbitals are delocalized over many atoms. Therefore, electrons occupying higher-energy conduction-band orbitals have higher mobility, and can carry charge currents within the material, while lower-energy, valence-band electrons generally cannot. An electron can be promoted 1112 from a valence-band orbital to a conduction-band orbital by any of different types of events that transfer energy to the electron, including interactions with energetic photons or with other electrons. Promotion, or excitation, of an electron produces a hole 1114 in the valence band. Holes can migrate through a material by various bond-rearrangements and electron migrations, and holes can therefore carry positive charge currents in an opposite direction from negative charge currents carried by conduction-band electrons. In metals, the valence-band orbitals and conduction-band orbitals overlap, so that ground-state electrons tend to be delocalized throughout the metal. Metals are therefore conducting at room temperatures. In insulators, the energy gap between the valence band and the conduction-band orbitals is relatively high, thereby forming a very large energy barrier to promotion of valence-band electrons to conduction-band orbitals. Semiconductors fall in-between insulators and metals, with a band gap sufficiently low to allow population of conduction-band orbitals at reasonable temperatures.

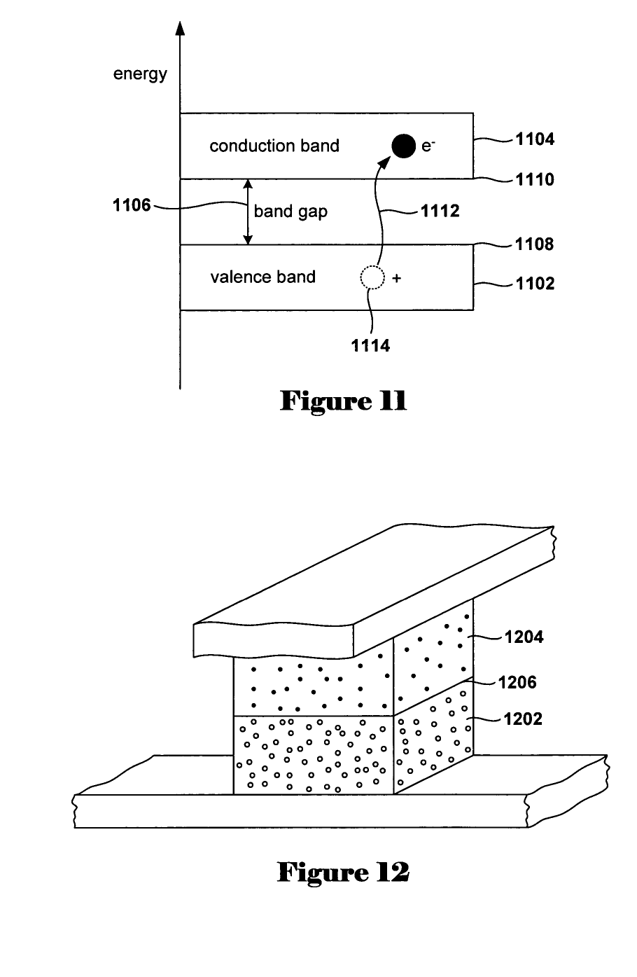

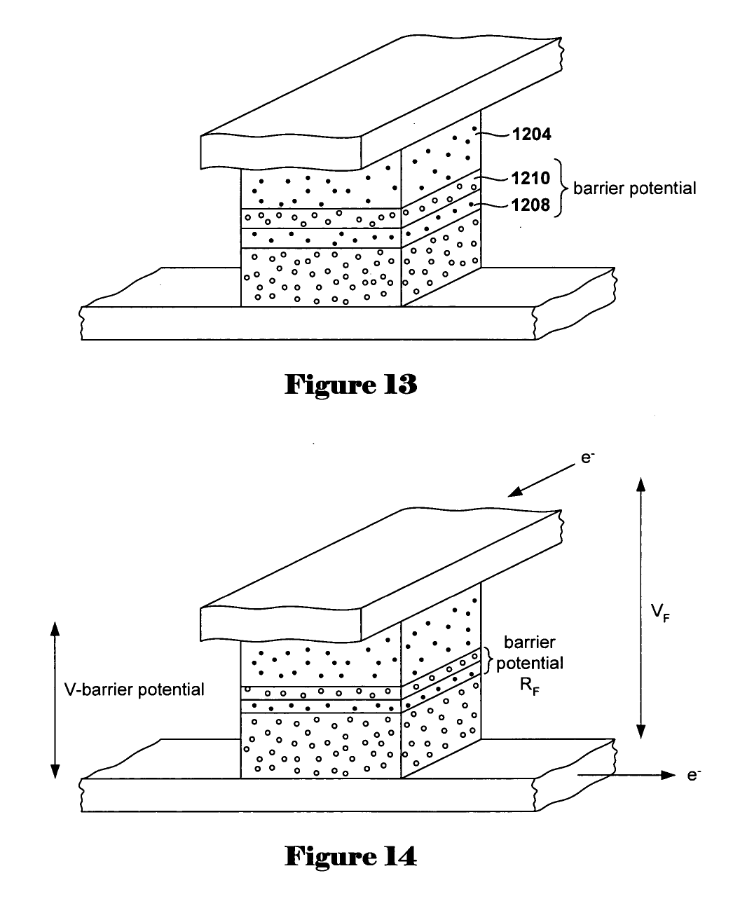

FIGS. 12-16 illustrate a diode component within a memory element. As shown in FIG. 12, the memory-element diode component comprises a first layer 1202 of a p-doped semiconductor and a second layer 1204 of an n-doped semiconductor layer. A p-doped semiconductor layer includes small amounts of trivalent atoms or electronegative compounds that result in creation of holes in the valence-band orbitals of the semiconductor. The n-doped layer includes small amounts of pentavalent atoms or electropositive compounds that contribute electrons to the conduction-band orbitals of the semiconductor. The surface 1206 at which the p-doped semiconductor joins with the n-doped semiconductor forms a rectifying junction. As shown in FIG. 13, an electric field is induced at the junction, and electrons migrate from the n-doped layer 1204 into a narrow region 1208 of the p-doped layer, resulting in a narrow region 1210 with an increased concentration of holes in the n-doped semiconductor layer adjoining the junction. The electron-rich region 1208 of the p-doped semiconductor and the electron deficient region 1210 of the n-doped semiconductor together produce a barrier potential, or, in other words, a small electrical field perpendicular to the junction and opposite in polarity from the electric field generally induced at the junction by the proximity of the p-doped and n-doped semiconductor layers. When a forward potential V_{F} is applied to the memory element, as shown in FIG. 14, the barrier potential is compressed, leading to a small voltage drop in a direction opposite to the applied potential due to the resistance R_{F} introduced by the barrier potential. Thus, the forward current I_{F} through the diode component of the memory element is proportional to

$$\frac{{V}_{F}}{{R}_{F}} .$$

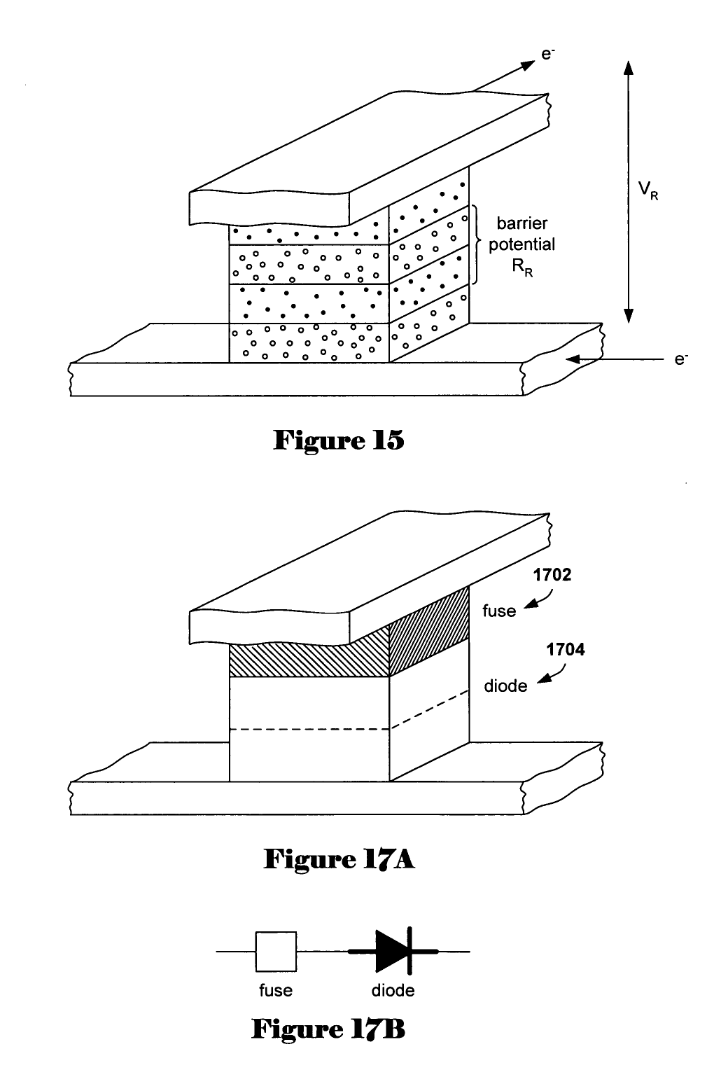

However, as shown in FIG. 15, when a potential of opposite polarity, V_{R}, is applied to the diode component of the memory element, the barrier regions expand, leading to a relatively high diode resistance R_{R}. The reverse current, I_{R}, is therefore relatively low, proportional to

$$\frac{{V}_{R}}{{R}_{R}} .$$

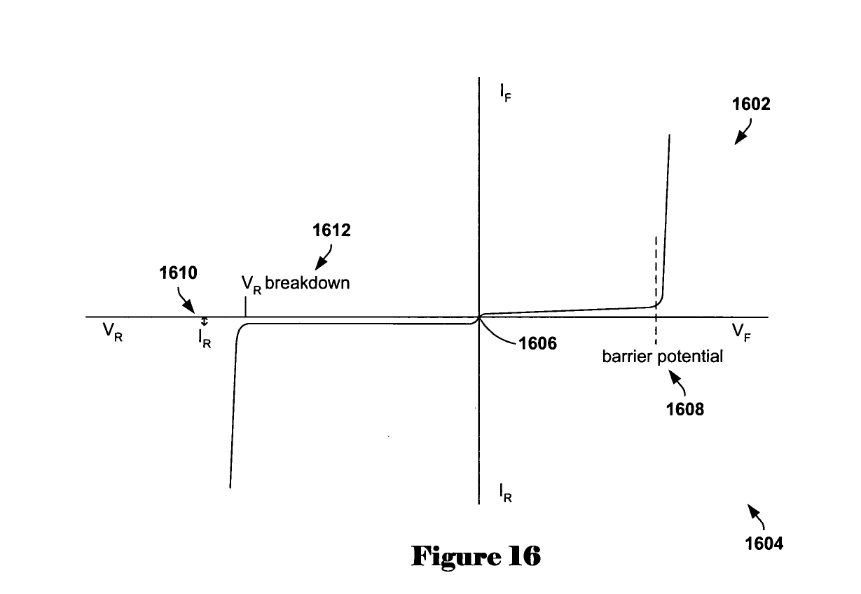

FIG. 16 is a graph showing the general form of the relationship between current and voltage in a diode. When forward biased, represented by voltages in the two right-hand quadrants 1602 and 1604 of the graph, the current passed by the diode rises slightly from 0 volts, at the origin 1606, to a barrier-potential voltage 1608. From that point on, the current rises steeply with increasing voltage. However, when reverse biased, the current passed by the diode is relatively small, and remains relatively small and constant with increasing reverse-polarity voltage until a breakdown voltage 1612 is reached, at which point the barrier layers adjoining the junction disintegrate, and current flows unimpeded by a barrier potential.

Using a diode component in a memory element addresses the reverse-current-associated problems discussed above with respect to FIGS. 9 and 6. In order to achieve two different resistance states, as discussed above with reference to FIGS. 7 and 8, a fuse component is included in the memory element. FIG. 17A shows a complete, previously described memory element including both a fuse component and a diode. In previously described memory elements, the fuse component 1702 is a layer of organic polymer, and the diode component 1704 is a silicon-based diode comprising layers of p-doped and n-doped silicon. In one type of memory element previously described, a p-i-n silicon diode is employed as the diode component. The organic-polymer fuse 1702 is stable within a range of relatively low magnitude applied voltages of either polarity, but irreversibly transitions to a high-resistance state when a voltage greater than a threshold WRITE voltage is applied for a time interval greater than a threshold WRITE time interval. Normally, the WRITE voltage threshold depends on the WRITE voltage-pulse-interval time, and vice versa, with the WRITE voltage threshold decreasing with increasing WRITE voltage-pulse application times. As shown in FIG. 17B, the previously described organic-polymer and silicon-diode memory element can be schematically described as a fuse in series with a diode.

In one embodiment of the present invention, rather than using separate fuse and diode components in a memory element, a combined-fuse-and-diode memory element (“CME”) is used. The CME offers numerous advantages over the previously described, separate-fuse-and-diode implementation. First, the CME is significantly less complex and cheaper to manufacture than the previously described memory element. Fabrication of semiconductor-based diodes with pn junctions requires several processing and patterning steps with strict alignment requirements. By contrast, the CME can be manufactured by simply overlaying a p-doped or n-doped semiconductor substrate with an organic-polymer-semiconducting substrate. The location of memory elements within the two layers is defined by the positions of the signal lines or other electrical contacts fabricated on the exterior sides of the two-layer semiconductor-junction sheet formed by the organic-polymer and semiconductor substrates. Discrete, separate memory elements can then be formed by etching in one or both directions perpendicular to the two-layer semiconductor-junction sheet. The CME also has a lower WRITE voltage and a much shorter WRITE-voltage-pulse interval than previously described memory elements. Therefore, the information-storage-and-retrieval device accessing a WORM memory comprising an array of CMEs can more efficiently access the WORM memory for both READ and WRITE operations.

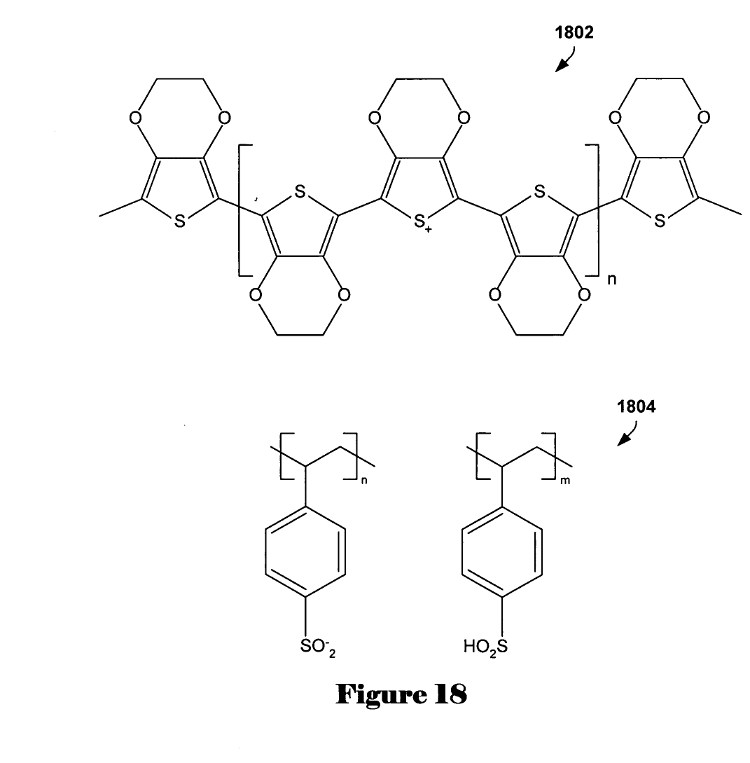

In one embodiment, the CME is an organic-on-inorganic heterojunction (“OIHJ”) diode (“OIHJD”). The organic layer is an organic-polymer film consisting of the two-component, conductive polymer mixture poly(3,4-ethylenedioxythiophene) and poly(styrene sulfonate) (“PEDT/PSS”). FIG. 18 shows the chemical structure of the PEDT/PSS polymer mixture, known by the trade name “Baytron® P.” The PEDT/PSS conductive polymer mixture is a mixture of a poly(3,4-ethylenedioxythiophene) polymers 102 and poly(styrene sulfonate) polymers 104. BaytronP® is prepared as an aqueous dispersion with a mixture of PEDT and PSS polymers. In general, the PEDT/PSS aqueous dispersion is spun onto a surface, to which it adheres upon drying to form an intrinsically conductive, transparent, and virtually colorless coating. PEDT/PSS has relatively high conductivity for an organic polymer, and can support current densities of greater than 200 amperes per cm². PEDT/PSS has good photostability and good thermostability, and is relatively resistant to hydrolysis. In addition, PEDT/PSS is generally a p-type semiconductor, with partial oxidation of the thiophene sulfur atoms leading to intrinsic bipolaron positive charge carriers. PEDT/PSS, following manufacture, has a relatively low resistivity, and supports relatively high current densities. When subjected to a relatively large magnitude voltage pulse, the current density supported by PEDT/PSS precipitously and irreversibly declines, producing a high resistivity state. Therefore, PEDT/PSS can serve as a fuse within a memory element to produce the needed low resistance and high resistance states corresponding to Boolean values “1” and “0.” Because PEDT/PSS is a semiconductor, PEDT/PSS can therefore form a heterojunction with an inorganic semiconductor, such as either p-doped or n-doped silicon. Thus, the PEDT/PSS not only serves as a fuse component in the memory element, but also serves as one layer of a two-layer diode.

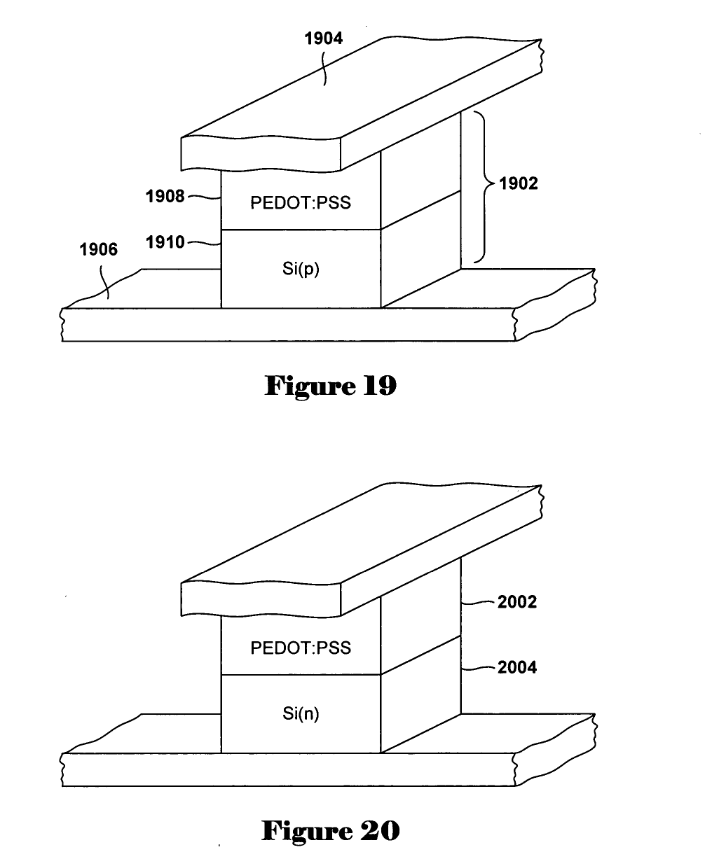

FIG. 19 shows a first memory-element embodiment of the present invention. In FIG. 19, the OIHJD 1902 is shown between two conductive contacts, or conductive signal lines, 1904 and 1906. A PEDT/PSS layer 1908 is layered on a p-type silicon layer 1910 to form a rectifying heterojunction. FIG. 20 shows a second memory-element embodiment of the present invention. In this second embodiment, a PEDT/PSS layer 2002 is layered on a p-type silicon layer 2004 to form a rectifying heterojunction.

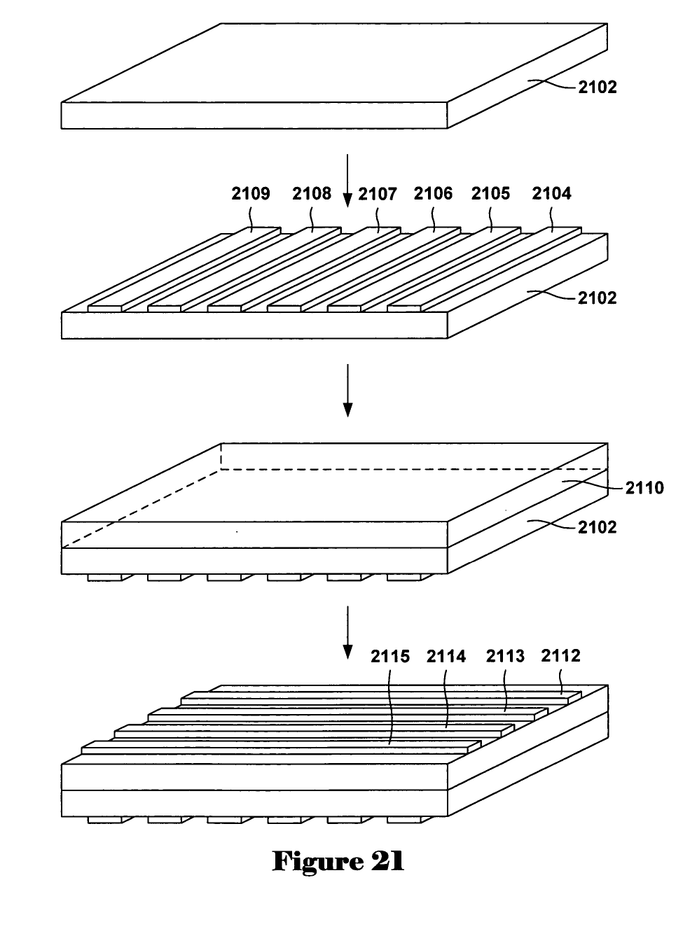

FIG. 21 illustrates a general manufacturing method for one type of CME that represents one embodiment of the present invention. Initially, a p-type or n-type silicon substrate 2102 is prepared. Next, signal lines or other electrical contacts 2104-2109 are fabricated on one surface of the semiconductor layer 2102. There are many ways to fabricate these conductive elements. They may be fabricated by vapor deposition through an interposed mask, or fabricated by etching the semiconductor layer, depositing metallic or other conductive elements, and then polishing the deposited conductor to produce discrete signal lines. Many other techniques commonly employed in IC fabrication may also be employed to fabricate the first set of signal lines. Next, a layer of PEDT/PSS 2110 is spun onto the opposite surface of the semiconductor layer 2102. Finally, a second set of conductive signal lines 2112-2115 is fabricated on top of the PEDT/PSS layer. The continuous-two-layer WORM memory can be etched, from either or both sides, to remove PEDT/PSS or both PEDT/PSS and semiconductor substrate outside of the overlap regions between signal lines to produce a WORM memory such as the WORM memory shown in FIG. 1. The WORM memory can then be encased in additional polymer, metal, or ceramic layers for mechanical protection and electrical isolation. Alternatively, a WORM memory, such as that shown in FIG. 1, can be fabricated, layer-by-layer, on the surface of a substrate, such as silicon dioxide or a nonconductive polymer. In yet additional alternative methods, the organic-polymer can be layered on top of the semiconductor substrate prior to fabrication of signal lines or other conductive contacts.

Next, experimental results obtained from investigating various CME prototypes are provided. Experiments were carried out on two types of CMEs: (1) Au/PEDT:PSS/n-type-Si CMEs; and (2) Au/PEDT:PSS/p-type-Si CMEs. These prototype CMEs exhibit rectification ratios

$$\frac{{I}_{{F}_{1}}}{{I}_{R}} of > {10}^{5} ,$$

and on/off current ratios

$$\frac{{I}_{{F}_{1}}}{{I}_{{F}_{0}}} of {10}^{4} \text{–} {10}^{5} .$$

The CME transitions from a low resistance to a high resistance state in 300 ns for 10V pulses, a significant improvement over previously described memory elements with separate fuse and diode components.

A 1:1.6 PEDT:PSS aqueous dispersion is spun onto a cleaned and polished surface of a doped Si substrate at 5000 rpm to form a film with a thickness of 50 nm. The doped Si substrate may be one of either a p-type or n-type Si wafer, with a resistivity of 0.005-0.02 Ω-cm, and is solvent cleaned and deoxidized in HF:H₂O (1:1) prior to PEDT:PSS deposition. Following deposition, the PEDT:PSS films are dried in a vacuum at 120° C. for 1 hour to remove excess water. Next, Au is evaporated through a shadow mask to form Au contacts with thicknesses of approximately 100 nm, the contacts, PEDT:PSS film, and Si substrate forming (25 μm)² CME devices. To prevent current spreading, the PEDT:PSS film surrounding the contacts is etched using an O₂ plasma at a flow rate of 50 sccm, a pressure of 100 mTorr, and 50 W RF power, or an Ar plasma, 50 sccm flow rate, 100 mTorr, and 20 W. The CME devices are quasi-statically switched using a WRITE pulse-voltage-ramp with 10 μs long, 100 mV steps applied for 0.5 μs to 4.0 μs, yielding duty cycles of 5% to 40%, respectively, or alternatively, rapidly switched with a single, high voltage (˜10 V) WRITE pulse.

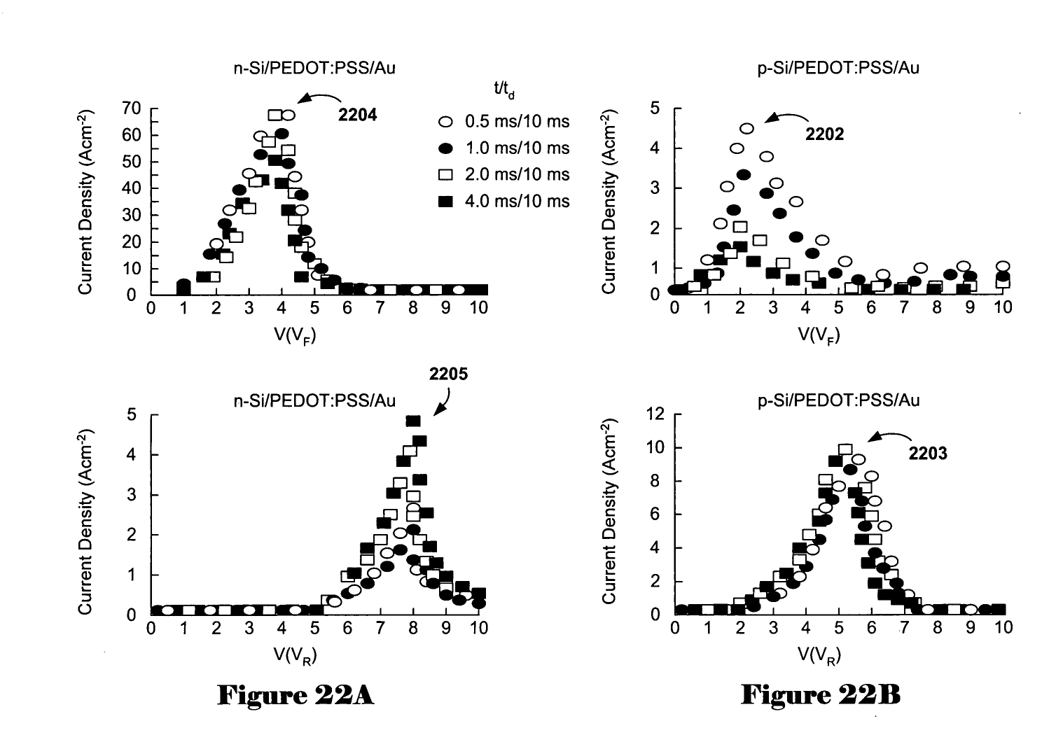

FIGS. 22A-B show the quasi-static conductivity switching characteristics of the prototype CMEs. The current rapidly increases with voltage up to a current peak 2204 of 4V, under forward bias (Au contact positive), and a current peak of 8V, under reverse bias, for the Au/PEDT:PSS/n-type-Si CME, as shown in FIG. 22A. The current rapidly increases with voltage up to a current peak 2202 of 2V, under forward bias (Au contact negative), and a current peak 2203 of 5V, under reverse bias, for the Au/PEDT:PSS/p-type-Si CME, as shown in FIG. 22B.

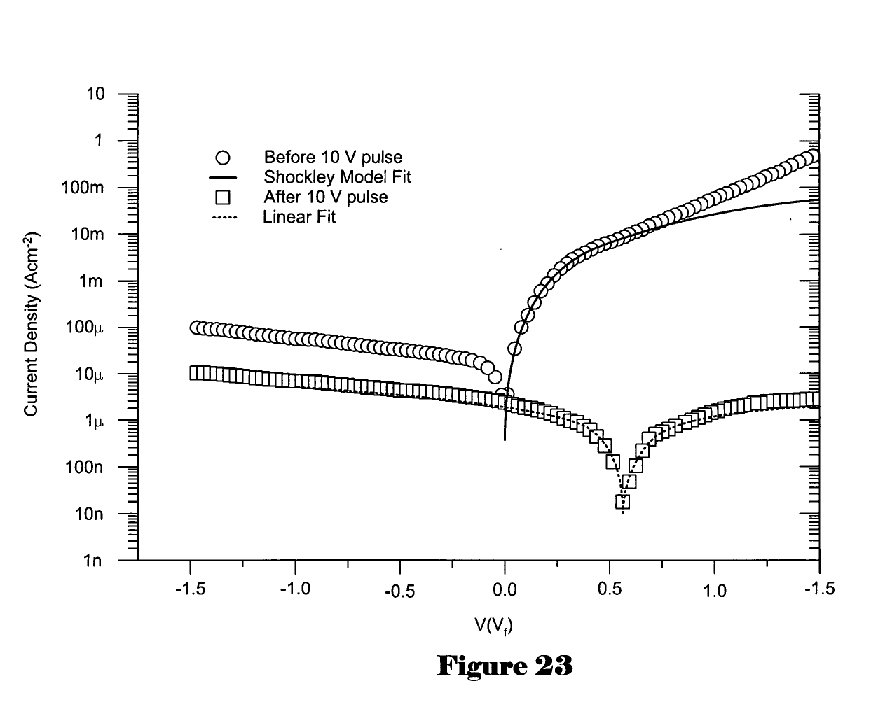

FIG. 23 shows the relationships between current densities and applied voltage for a prototype CME before and after application of a WRITE voltage pulse. As shown in FIG. 23, over much of the forward biasing applied voltage range, the ratio of the current density supported by the CME in a low resistance state and the current density supported by the CME in a high resistance state is ˜10⁵. Plasma-etching the PEDT:PSS layer surrounding the Au contact of a CME improves the rectification ratio

$$\frac{{I}_{{F}_{1}}}{{I}_{R}}$$

by up to two orders of magnitude, with the reverse-bias current I_{R} decreasing by a factor >10³ after etching. The shape of the forward-biased current density vs. voltage (J-V) characteristic at V_{F}<0.5V follows that of a conventional p-n junction diode with specific resistance Rₛ. At higher forward bias voltages, the slope of the J-V characteristic decreases with respect to that of a conventional p-n junction diode, due to polymer series resistance. At the highest current densities, the current increases more rapidly than predicted by a conventional p-n junction diode J-V characteristic, due to the onset of Joule heating. This further decreases Rₛ prior to the onset of conductivity switching.

Under reverse bias, the current increases approximately linearly with voltage, which is somewhat higher than J˜V^{1/2} expected from simple generation and recombination currents in the Si substrate. This linear voltage dependence is evidence for shunt currents at the periphery of the etched contact. The J-V characteristics are consistent with previous reports of OIHJD devices consisting of small molecular weight organics, such as 3,4,9,10 perylenetetracarboxylic dianhyrdride deposited on Si substrates.

After switching, the current in both the forward and reverse biased directions becomes symmetrical, maintaining only the approximately linear dependence on voltage, as observed for reverse biased as-deposited OIHJDs. This again suggests that the slope is due primarily to shunt currents along the surface of the Si wafer. Also, the current drops to zero only at Vₒ=0.5V in this voltage sweep. This offset and the residual current at OV is due to charge detrapping from the high resistivity switched film.

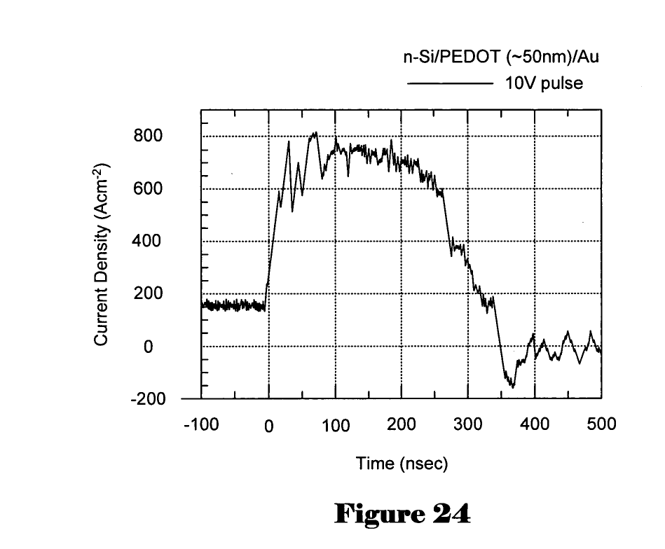

FIG. 24 shows the relationship between current density and time during application of a voltage pulse to a prototype memory element that represents one embodiment of the present invention. The current rises with applied pulse voltage, and then decreases dramatically after the onset of switching, with the switching delay decreasing with increasing voltage. For a voltage pulse of 10V, the conductivity switches within 300 ns.

The switching of a PEDT:PSS film from a high to a low conductivity state has been explained by a simple redox reaction. Electrons injected into the polymer film lead to the reduction of the oxidized PEDT:PSS chains. To stabilize the PEDT:PSS in the neutral state, the surrounding PSS⁻ is oxidized by injected holes at high current. Also, as has been previously proposed, the temperature of the polymer film increases by 100° C. to 200° C. during switching, leading to PSS⁻ reacting with residual water to form a stable neutral species, PSSH. The importance of thermal effects is clearly evident from the change in magnitude of the switching current in the quasi-static and short pulse transient behaviors observed in FIGS. 22A-B and 24, as well as the apparent onset of “thermal runaway” at high J shown in FIG. 23. That is, currents <10 A/cm² can lead to switching under quasi-static conditions, whereas currents approaching 1 kA/cm² are observed under rapid voltage pulse transients. Furthermore, as is particularly apparent in the case of the forward biased p-type Si substrate, the current required for switching decreases from 4 A/cm² to only 0.5 mA/cm² as the step duration increases from 0.5 μs to 4 μs. These trends are also apparent, although they are somewhat weaker, under reverse bias, and also for n-type Si substrates.

In previously described, separate-fuse-and-diode devices, double-injection gain is observed to increase the hole density, as evidenced by rapid PEDT:PSS oxidation, due to hole injection from an indium-tin-oxide contact. In the CMEs that represent embodiments of the present invention, doped Si is instead used as the contact. This presents a barrier at the OIHJ interface that prevents significant injection of the minority counter carrier, resulting in a reduced current for switching as well as a significant reduction in the switching delay.

Although the present invention has been described in terms of a particular embodiment, it is not intended that the invention be limited to this embodiment. Modifications within the spirit of the invention will be apparent to those skilled in the art. For example, other inorganic semiconductors, in addition to silicon, may be used as the inorganic layer in an OIHJD memory element. Similarly, other types of organic polymers, in addition to PEDT/PSS may be employed as the second layer of the OIHJD CME. It may also be possible to employ a second, different organic-polymer layer, rather than an inorganic semiconductor, to produce an organic-to-organic heterojunction device as a CME. Different levels and types of doping may be employed to alter the characteristics of the CME layers, and a variety of different types and configurations of WORM memories may be fabricated from CMEs, including different types and arrangements of conductive signal lines or contacts. Dense, multi-layered WORM memories may be constructed from multiple layers of CMEs. In addition to finding use in inexpensive and reliable WORM memories, the CME of the present invention may also find use in various other types of electronic components. It may also be possible, by selecting different types of organic-polymer layers, to produce dynamic CMEs that can be repeatedly written and read, rather than write-once CMEs.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purpose of illustration and description. They are not intended to be exhaustive or to limit the invention to the precise forms disclosed. Obviously many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A two-component memory element comprising:
a first component that serves as both a fuse and a semiconductor; and
a second, semiconductor component that, together with the first component, forms a rectifying junction.

2. The two-component memory element of claim 1 wherein the first component comprises an organic semiconductor polymer film with two stable states.

3. The two-component memory element of claim 2 wherein the organic polymer film comprises a mixture of poly(3,4-ethylenedioxythiophene) and poly(styrene sulfonate).

4. The two-component memory element of claim 1
wherein the second component is an inorganic semiconductor; and
wherein the rectifying junction is a heterojunction.

5. The two-component memory element of claim 4 wherein the second component comprises one of:
p-doped silicon; and
n-doped silicon.

6. The two-component memory element of claim 1
wherein the first component is electrically connected to a first conductive contact; and
wherein the second component is electrically connected to a second conductive contact.

7. The two-component memory element of claim 6 wherein the first conductive contact is a row signal line of a passive matrix memory and the second conductive contact is a column signal line of a passive matrix memory.

8. The two-component memory element of claim 1 wherein the first component stores a Boolean value “0” when the first component is in a first stable conductivity state and stores a Boolean value “1” when the first component is in a second stable conductivity state.

9. The two-component memory element of claim 8
wherein the first component is in the first stable conductivity state following manufacture; and
wherein the conductivity state of the first component is switched to the second stable conductivity state by application of a voltage greater than a threshold voltage to the two-component memory.

10. A memory comprising:
a first set of row signal lines;
a second set of column signal lines; and
two-component memory elements interconnecting the first set of row signal lines to the second set of column signal lines at locations in the memory where the row signal lines overlap column signal lines.

11. The memory of claim 10 wherein the two-component memory elements each comprise:
a first semiconductor fuse component; and
a second semiconductor component that forms a rectifying junction at a plane of contact with the first semiconductor fuse component.

12. The memory of claim 11 wherein the first semiconductor fuse component has two stable conductivity states that represent two different binary values.

13. The memory of claim 12 wherein the first semiconductor fuse component can be switched from a first stable conductivity state to a second stable conductivity state by application of a voltage greater than a threshold voltage to the first semiconductor fuse component.

14. The memory of claim 11 wherein the first semiconductor fuse component comprises a mixture of poly(3,4-ethylenedioxythiophene) and poly(styrene sulfonate).

15. The memory of claim 11 wherein the second semiconductor component comprises one of:
p-doped silicon; and
n-doped silicon.

16. A method for fabricating a two-component memory element, the method comprising:
selecting a first semiconductor substrate;
preparing a surface of the first semiconductor substrate to receive a rectifying-junction-forming second layer;
applying, as the second layer, an organic semiconductor second layer to the prepared surface of the first semiconductor substrate to form a rectifying heterojunction; and
applying conductive contacts to non-junction surface of the second layer and to the non-junction surface of the first semiconductor substrate.

17. The method of claim 16 wherein wherein the first semiconductor substrate comprises one of:
p-doped silicon; and
n-doped silicon.

18. The method of claim 17 wherein the second layer comprises a mixture of poly(3,4-ethylenedioxythiophene) and poly(styrene sulfonate).
